(19) United States
(12) Patent Application Publication
(10) Pub. No.: US 2001/0024769 A1
(43) Pub. Date: Sep. 27, 2001

(54) Method for removing photoresist and residues from semiconductor device surfaces

(76) Inventors: Kevin Donoghue, Richmond, CA (US); Todd Stepp, Castro Valley, CA (US); Gerald M. Cox, Lafayette, CA (US); Kristel Vanbaekel, Pleasant Hill, CA (US)

Correspondence Address: GREGORY SCOTT SMITH, P O BOX 2192, FREMONT, CA, 94536

(21) Appl. No.: 09/780,873

(22) Filed: Feb. 8, 2001

Related U.S. Application Data
(60) Provisional application No. 60/181,131, filed on Feb. 8, 2000.

(51) Int. Cl. G03F 7/36; C25F 3/30; B08B 6/00

(52) U.S. Cl. 430/329; 216/67; 134/1.2; 134/1.3

(57) ABSTRACT

The present invention is a novel process for removing photoresist, post-etch polymers, and other assorted residues from semiconductor devices incorporating low-κ dielectric materials. In general the invention comprehends using a substantially oxygen free reducing plasma that is preferably high in hydrogen content, rather than the oxidizing plasma typically used. The invention generally comprises the steps of (a) introducing a semiconductor device including a dielectric material comprising an organic silicon glass into a chamber, (b) introducing effective amounts of a hydrogen containing gas such as ammonia or methane, and (c) decomposing the gases and plasma phase reacting the decomposed gases with the photoresist and or other residues to volatilize the residues. In one preferred embodiment of the method the etchant gasses include ammonia, helium, and a forming gas preferably comprising hydrogen and nitrogen. In a second preferred embodiment, the etchant gasses include ammonia and a forming gas comprising hydrogen and helium. In a third preferred embodiment, the forming gas is replaced with water vapor preferably created in a catalytic moisture generator by combining hydrogen in a helium carrier gas, with oxygen.

### CROSS REFERENCE TO OTHER APPLICATIONS

This application claims the benefit of U.S. Provisional Patent Application Number 60/181,131, filed Feb. 8, 2000.

### FIELD OF THE INVENTION

This invention relates generally to ammonia based methods for stripping photoresist and post-etch polymers during integrated circuit manufacturing processes, and more particularly to processes for removing photoresist and post-etch polymers or residues from the surface of integrated circuit devices with a combination of gasses, including ammonia.

### BACKGROUND OF THE INVENTION

Conventional fabrication of an integrated circuit device involves placing numerous device structures, such as MOFSETs, bipolar transistors, and doped contact regions, on a single monolithic substrate. The device structures are then electrically interconnected with horizontal conductive lines or structures formed in layers and vertical conductive structures called vias between layers so as to implement desired circuit function.

In order to produce ever faster and smaller integrated circuit devices, the integrated circuit industry has continuously increased the density of the device structures on the substrate surface. The increasingly higher device structure density has resulted in a continuous reduction in the separation between conductive structures and layers of materials, a reduction in the width and thickness of conductive lines and an increase the total length of the conductive lines. This has further resulted in a number of adverse effects. For example, by reducing the spacing between conductive materials in the integrated circuit device, an increase in a phenomenon known as parasitic capacitance or capacitive crosstalk is observed, wherein a change in voltage on one conductive structure effect the voltage on nearby conductive structures. As the conductive structures of an integrated circuit are packed more closely together this capacitance between the conductive structures increases. One solution is to reduce the capacitance by using insulating or dielectric materials having a lower dielectric value (κ) than the widely used silicon oxides.

A variety of such low-κ materials are currently under consideration and development. These new dielectrics can be organic or inorganic in composition, and are typically deposited using chemical vapor deposition (CVD) methods, or by spin-on glass (SOG) techniques. One challenge encountered in using the new materials relates to the photoresist stripping and post-etch polymer removal steps used in current manufacturing processes. Generally, current known photoresist stripping and polymer removal methods, particularly those using O₂, have adverse effects on the low-κ materials. Specifically, the oxygen can attack the bonds between the atoms in inorganic low-κ materials such as Si—H and Si—C oxidizing them to Si—O and SiOH respectively. The presence of Si—O and Si—OH may adversely effect the κ value of the material. When using organic low-κ materials, the O₂ plasma may oxidize the carbon low-κ material much as it does the photoresist forming volatile CO and CO₂, thus removing low-κ material that was intended to remain.

What is needed are methods for photoresist stripping and post-etch polymer removal that avoid the disadvantages of the prior art.

### SUMMARY OF THE INVENTION

Accordingly, the present invention is a novel process for removing photoresist (sometimes referred to as “resist”), post-etch polymers and other assorted residues (sometimes referred to hereafter as “polymer,” “sidewall polymer,” “via veil,” or “residue”) from semiconductor devices incorporating low-κ dielectric materials. This process may be useable on a variety of organic and inorganic low-κ materials, however, this specification will emphasize its use on organo-silica glass—type (OSG) low-κ materials.

The novel method of the present invention comprehends using a reducing plasma that is preferably high in hydrogen content and substantially oxygen free, rather than the oxidizing plasma typically used. A hydrogen containing gas such as Ammonia or Methane is used as the primary source of hydrogen radicals that remove the photoresist and post strip residues by chemical reduction instead of chemical oxidation. Ammonia has been found to be particularly effective in removing photoresist and post strip residues from materials that are sensitive to the standard chemistry using oxygen.

In general, the invention is a method for removing photoresist and other residues comprises the steps of (a) introducing a semiconductor device into a chamber including a dielectric material comprising an organo-silica glass, (b) introducing effective amounts of a hydrogen containing etchant gas such as ammonia and or methane to remove a layer of photoresist and or other residues, (c) decomposing the etchant gasses and plasma phase reacting the decomposed gases with the photoresist and or other residues to volatilize the residues.

In one preferred embodiment of the method the etchant gasses include ammonia, helium, and a forming gas preferably comprising approximately 5% hydrogen and 95% nitrogen. In a second preferred embodiment, the etchant gasses include ammonia and a forming gas comprising approximately 4% hydrogen and approximately 96% helium. In a third preferred embodiment, the forming gas is replaced with water vapor preferably created in a catalytic moisture generator.

Three example methods of the invention will be discussed including (1) organo-silica glass photoresist stripping using an ammonia based plasma with H₂/N₂ forming gas, (2) organo-silica glass photoresist stripping using an ammonia based plasma with H₂/He forming gas, and (3) organo-silica glass photoresist stripping using an ammonia based plasma with H₂O process gas substituted for the forming gas of prior listed methods.

### BRIEF DESCRIPTION OF THE DRAWINGS

FIG. 1 is a cutaway side view of a semiconductor device, prior to conductive lines being formed in the first metal layer, with a metal layer disposed over underlying layers, a low-k dielectric layer disposed over the metal layer, and a layer of photoresist disposed over the low-κ dielectric layer with apertures formed in the photoresist to define areas where the dielectric will be etched.

FIG. 2 is a cutaway side view of the semiconductor device of FIG. 1 after the low-κ dielectric has been etched.

FIG. 3 is a cutaway side view of the semiconductor device of FIG. 2 after the method of the invention has been applied to remove the photoresist layer and any sidewall polymers or residues.

### DETAILED DESCRIPTION OF THE INVENTION

Accordingly, the present invention is a novel process for removing photoresist, post-etch polymers, and other assorted residues from semiconductor devices incorporating low-κ dielectric materials. This process may be useable on a variety of organic and inorganic low-κ materials, however, this disclosure will emphasize its use on organo-silica glass—type low-κ materials. In general, the invention comprehends using a reducing plasma that is preferably high in hydrogen content and substantially oxygen free to prevent oxidation of the low-κ material, rather than the oxidizing plasma typically used.

The term “substantially oxygen free” is used in this application to mean that the quantity of oxygen molecules in the reaction chamber is low enough that the oxygen does not significantly influence or affect the results. There is one exception to the above definition relating to embodiments of the method including the addition of water vapor, wherein the term “substantially oxygen free” means that the oxygen level in the reaction chamber is low enough that there is no appreciable or unacceptable oxidation damage to the low-κ dielectric material portion of the semiconductor devices being treated therein.

The methods of the invention may be implemented with any suitable plasma stripping or etching system. In the methods described, reactive species derived from etchant gases are generated in a plasma, and these species diffuse to the photoresist and/or post-etch polymers and/or residues where the reactive species chemically react to produce desired chemical changes in the nature of the photoresist or residues. Typically the reaction removes the photoresist and residues by creating volatile by-products that are de-sorbed from the surface of the semiconductor device. However, the desired reaction could instead result in a residue that is prepared for removal in a subsequent process step.

The method of the invention may be implemented with any suitable plasma stripping or etching system, and is not limited to the particular configurations that may be disclosed herein. The assembly of such systems is well known, and many such assemblies exist in a variety of configurations. The exact configuration of the system may be varied as required, and the details of the particular system used will depend on the parameters of the process that must be controlled, and the specific application of the system. However, microwave plasma systems are currently preferred for use with the method of the invention. Plasma stripping and etching systems generally comprise a number of interconnected components including (a) an etching chamber that can be evacuated to reduce the gas pressures therein, (b) a pumping system for establishing and maintaining the desired pressure, (c) various pressure gauges to monitor the pressure in the chamber, (d) apparatus allowing the pressure in the chamber and the flow rate of gasses into the chamber to be controlled independently, (e) a power supply, (f) gas handling apparatus for metering and controlling the flow of reactant gases, and (g) one or more means for creating a plasma and for maintaining the plasma.

In general, one or more process gasses are introduced into the chamber from one or more gas sources through an inlet pipe. A microwave source, preferably at the inlet pipe, causes a microwave plasma to be formed at the inlet pipe, thus discharging a reactive gas with a high concentration of free radicals. The gas passes through openings in a top electrode mounted above a wafer, where additional energy may be applied to the plasma. Under appropriate conditions, the reactive gas can decompose and remove unwanted residues and photoresist by converting the photoresist and residues to volatile gases. A vacuum draws the gasses away through an exhaust tube, and also maintains the pressure in the chamber within a desired range. Such processes are well known in the prior art for processing currently used dielectric materials such as SiO₂. However, current known photoresist stripping and polymer removal methods, particularly those using O₂, have adverse effects on new lower-κ dielectric materials.

The novel method of the present invention comprehends using a reducing plasma that is preferably high in hydrogen content and oxygen free to prevent oxidation, rather than the oxidizing plasma typically used. A hydrogen containing gas such as Ammonia or Methane is used as the primary source of hydrogen radicals that remove the photoresist and post strip residues by chemical reduction instead of chemical oxidation. Ammonia has been found to be particularly effective in removing photoresist and post strip residues from materials that are sensitive to the standard chemistry using oxygen.

In general, the invention is a method for removing photoresist and other residues comprising the steps of (a) introducing a semiconductor device into a chamber, preferably but not necessarily including a dielectric material comprising an organic silicon glass, (b) introducing effective amounts of hydrogen containing etchant gas such as ammonia or methane, (c) decomposing the gasses and plasma phase reacting the decomposed gases with the photoresist and/or other residues to treat or volatilize the residues. The method is preferably performed in a substantially oxygen free environment. Other gasses, in addition to ammonia, may be introduced during step (c) including but not limited to nitrogen, helium, hydrogen, and water vapor. The method of the invention may be used with many known integrated circuit manufacturing processes including, but not limited to, current conventional fabrication processes, damascene processes, and copper damascene processes.

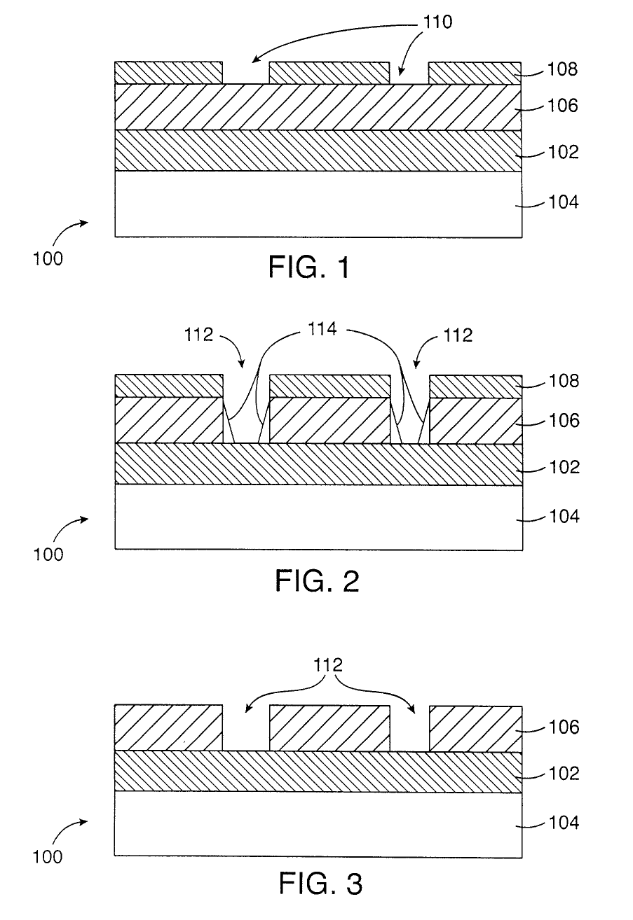

FIGS. 1 through 3 illustrate one application or example of use of the method of the invention in a process for forming via holes in a layer of dielectric material deposited over a metal layer in which conductive lines have been formed. FIG. 1, shows a semiconductor device 100 on which known methods are used to form conductive lines in a metal layer 102 disposed over the underlying layers 104. The metal layer 102 typically actually comprises several layers of different metals or alloys including barrier layers, seed layers, etc. A dielectric layer 106 is then formed over the metal layer 102. Any desired dielectric material may be used, and the particular dielectric material used is not critical to the invention, although the use of a low-k dielectric material is preferred. The method of applying the dielectric layer 106 is also not critical to the invention, and examples of acceptable methods for depositing the dielectric layer 106 include known chemical vapor deposition methods, physical vapor deposition methods, and spin-on deposition methods. Then, using known methods, the dielectric layer 106 is planarized, and coated with a photoresist mask. The dielectric layer 106 typically comprises a number of layers which may include several types of dielectrics, and silicon oxide and or silicon nitride caps or barriers.

Conventional spin-on methods are preferred for forming the photoresist layer 108, however, other methods of applying the photoresist 108 may be acceptable. To enhance the photo-lithographic process, anti-reflective coatings may be deposited prior to the photoresist 108. The photoresist 108 is cured in a conventional manner that depends on the particular photoresist material chosen. Typically, the photoresist 108 is exposed through a mask to an agent such as UV light, electron beam, or X-rays. Then, the photoresist 108 is developed to produce regions or gaps 110 where the photoresist 108 has been removed to allow etching materials access to the underlying dielectric layer 106, as is seen in FIG. 1

Referring to FIG. 2, the dielectric layer 106 underlying the photoresist layer 108 is etched through the gaps 110. This results in the formation of via holes 112 to receive conductive material that will form vias. The particular etching method is not critical to the invention. Typically, certain residues remain after etching, including sidewall polymers, or via veils 114, as shown. Generally there is some over etching to insure that quality vias have been formed, and this results in inorganic material being incorporated into the via veils 114.

Application of the methods of the invention results in the semiconductor device 100 of FIG. 3, which shows the photoresist 108 and the via veils 114 removed. Although a conventional via etching process has been shown, the method of the invention may be used in many other semiconductor manufacturing processes.

As previously stated, the method steps of the invention comprises the steps of (a) introducing a semiconductor device into a chamber including a dielectric material, preferably a low-k dielectric material, (b) introducing effective amounts of hydrogen containing etchant gas such as ammonia or methane, (c) decomposing the gasses and plasma phase reacting the decomposed gases with the photoresist and/or other residues to treat or volatilize the residues. Other gasses, in addition to ammonia, may be introduced during step (c) including but not limited to, helium, hydrogen, water vapor, and forming gas.

In one preferred embodiment of the method the etchant gasses include ammonia, helium, and a forming gas preferably comprising approximately 5% hydrogen and 95% nitrogen. In a second preferred embodiment, the etchant gasses include ammonia and a forming gas comprising approximately 4% hydrogen and approximately 96% helium. In a third preferred embodiment, the forming gas is replaced with water vapor preferably created in a catalytic moisture generator by combining approximately 4% hydrogen and approximately 96% helium, with oxygen.

The forming gas, as defined herein, is a gas mixture that contains hydrogen in an inert (non-flammable) gas, such as argon, helium, or nitrogen. Forming gas allows the use of hydrogen as a process gas, but with a reduced flammable hazard. The forming gas can be made in any desired percentage hydrogen content, however, a hydrogen content of 5% or less is preferred.

The word “inert” when applied to components of the forming gas refers only to the gases flammability. Even though the “inert” portion of the forming gas is inert when considered for flammability, or reaction within the CMG, it may not necessarily be inert when reacting with the wafer in the plasma chamber. As the inert portion of the gas passes downstream, it too is part of the plasma in the reactor chamber, and the results of the method can be affected by the “inert” portion.

The methods described above will be disclosed in more detail below by way of example. These processes may include several steps, or sub-steps, the order of which may vary from one situation to another.

### EXAMPLE 1

The first example discloses a method using an ammonia-based plasma with an H₂/N₂ Forming Gas. The preferred process variables used in this example are as follows:

(1) The reaction chamber gas pressure is preferably between 200 and 2100 mtorr, and more preferably approximately 500 to 800 mtorr.

(2) The Microwave power level is preferably between 800 and 4,400 watts, and more preferably approximately 2700 watts.

(3) The platen temperature is preferably 15 to 250 degrees centigrade, and more preferably approximately 250 degrees centigrade.

(4) The ammonia gas flow is preferably between 200 and 5,500 sccm, and more preferably approximately 1360 sccm.

(5) The helium flow is preferably between 0 and 1,500 sccm, and more preferably approximately 1360 seem.

(6) The forming gas flow is preferably between 0 and 5,500 sccm, and more preferably approximately 4080 sccm. Furthermore, the forming gas preferably comprises approximately 5% Hydrogen and 95% Nitrogen.

(7) The RF power level is preferably between 0 and 600 watts.

The experiment was performed on organo-silicate glass substrate samples. The results were evaluated by scanning electron microscope, and the surface of the oxide hard mask on the organic silicon glass substrate appeared clear of all residue and photoresist and the via hole appears intact and free from sidewall residues. The results on blanket coated samples were evaluated with the use of an ellipsometer to determine the thickness and refractive index. The refractive index is used to screen for a change in the physical properties of the low-κ dielectric material. The analysis of the data from the ellipsometer showed negligible degradation of the refractive index of the material, with the observed degradation on the order of less than one percent.

### EXAMPLE 2

The second embodiment of the method of the invention comprises an ammonia-based plasma with an H₂/He Forming Gas. The substitution of H₂/He forming gas for the H₂/N₂ forming gas, as shown in the previous example, appeared to give similar results with a faster photoresist removal rate. The preferred process variables used in this example are as follows:

(1) The reaction chamber gas pressure is preferably between 200 and 2100 mtorr, and more preferably approximately 800 mtorr.

(2) The Microwave power level is preferably between 800 and 4,400 watts, and more preferably approximately 2700 watts.

(3) The platen temperature is preferably 15 to 250 degrees centigrade, and more preferably approximately 250 degrees centigrade.

(4) The ammonia gas flow is preferably between 200 and 3,000 sccm, and more preferably approximately 1360 sccm.

(5) The forming gas flow is preferably between 4,000 and 6,000 sccm, and more preferably approximately 5440 sccm. Furthermore, the forming gas preferably comprises approximately 4% Hydrogen and 96% Helium.

(6) The RF power level is preferably between 0 and 600 watts.

As before, the results were evaluated by SEM microscope observations, and the surface of the oxide hard mask appeared clear of all residue and photoresist and the via holes appears intact and clear of sidewall residues.

### EXAMPLE 3

The third embodiment of the method of the invention comprises the use of an ammonia-based plasma with H₂O. The substitution of H₂O as a process gas for the H₂/N₂ forming gas, as discusses previously, may give similar results. As previously mentioned, the water vapor is preferably produced in a catalytic moisture generator (CMG) by reacting excess H₂ in a He carrier with O₂. However, this process should be effective with H₂O being derived from other sources such as heated liquid sources. When using a CMG for this process, it is preferable to run with stoichiometric excess of H₂ so that the O₂ is substantially consumed in the CMG unit and not allowed into the reactor as free O₂.

When H₂ containing forming gas is used together with oxygen in a catalytic moisture generator to make water vapor, the reaction is exothermic. At flows, near or above 15 liter per minute, the temperature of a typical catalytic moisture generator casing can rise from 100 to 300 C. In addition, the higher the concentration of hydrogen in the forming gas, the hotter the reaction. For reasons of safety, the hydrogen containing forming gas preferably comprises less than 6% H₂.

In the exemplary method described below, there is an inherent relationship between the amount of water vapor and the amount of inert gas. As one introduces the forming gas through the CMG, for each hydrogen molecule (H₂) entering, there is one water molecule (H₂O) formed. And if stoichiometric amounts of oxygen flow are used, then the effluent gas is merely water vapor and the inert gas. For example, if a forming gas that had 4% hydrogen in helium was used (and there was a stoichiometric amount of oxygen), then the effluent from the CMG is 4% water vapor and the remaining 96% is helium. In some embodiments it is preferred that no additional amount of inert gas is introduced into the process stream above and beyond the amount that enters the CMG.

The preferred process variables used in this example are as follows:

(1) The reaction chamber gas pressure is preferably between 800-1600 mtorr, and more preferably approximately 800 mtorr.

(2) The Microwave power level is preferably 1,700 to 2,700 watts, and more preferably approximately 2700 watts.

(3) The platen temperature is preferably 150 to 250 degrees centigrade, and more preferably approximately 250 degrees centigrade.

(4) The ammonia gas flow is preferably between 1,300 and 4,300 sccm, and more preferably approximately 2,225 sccm.

(5) The forming gas flow is preferably between 4,000 and 6,000 seem, and more preferably approximately 5440 sccm. Furthermore, the forming gas preferably comprises approximately 4% Hydrogen and 96% Helium.

(6) The flow of Oxygen is preferably at a rate approximately stoichiometrically equivalent to the hydrogen flow rate, plus or minus up to 50%.

As before, the results were evaluated by SEM microscope observations, and the surface of the oxide hard mask appeared clear of all residue and photoresist and the via holes appears intact and clear of sidewall residues.

To those skilled in the art, many changes and modifications will be readily apparent from the consideration of the foregoing description of a preferred embodiment without departure from the spirit of the present invention; the scope thereof being more particularly pointed out by the following claims. For example, it is possible to integrate the process steps of the invention in integrated circuit fabrication processes other than those discussed herein. The description herein and the disclosures hereof are by way of illustration only and should not be construed as limiting the scope of the present invention which is more particularly pointed out by the following claims.

What is claimed is:

1. A method for removing photoresist and for removing organic and inorganic residues from the surface of a semiconductor device, the method comprising:
(a) placing a semiconductor device, having a residue formed thereon, into a reaction chamber,
(b) creating and maintaining a substantially oxygen free environment within the reaction chamber
(c) introducing etchant gasses into the reaction chamber, the etchant gasses including a hydrogen containing gas selected from the group consisting of CH₄ and NH₃,
(d) applying energy to the etchant gasses to generate a plasma,
(e) exposing the semiconductor device to the plasma for a selected period of time.

2. The method of claim 1, wherein the etchant gasses include a hydrogen containing forming gas.

3. The method of claim 2, wherein the hydrogen containing forming gas includes a dilutant selected from the group consisting of nitrogen, helium, argon, or nitrogen.

4. The method of claim 1, wherein water vapor is introduced to the reaction chamber.

5. The method of claim 1 wherein the semiconductor device comprises a low-k dielectric material.

6. The method of claim 5 wherein the low-k dielectric material is an organo-silicate dielectric material.

7. A method for removing photoresist and for removing organic and inorganic residues from the surface of a semiconductor device, the method comprising:
(a) placing a semiconductor device comprising a low-k dielectric material, into a reaction chamber, the semiconductor device having a residue formed thereon,
(c) creating and maintaining a substantially oxygen free environment within the reaction chamber
(b) introducing etchant gasses into the reaction chamber, the etchant gasses including a hydrogen containing gas,
(c) applying energy to the etchant gasses to generate a plasma,
(d) exposing the semiconductor device to the plasma for a selected period of time.

8. The method of claim 7, wherein the hydrogen containing gas comprises at least one gas selected from the group consisting of CH₄ and NH₃.

9. The method of claim 7, wherein the etchant gasses include a hydrogen containing forming gas.

10. The method of claim 7, wherein the hydrogen containing forming gas includes a dilutant selected from the group consisting of helium, argon, or nitrogen.

11. The method of claim 7, wherein water vapor is introduced to the reaction chamber.

12. A method for removing photoresist and for removing organic and inorganic residues from the surface of a semiconductor device, the method comprising:
(a) placing a semiconductor device comprising a low-k dielectric material, into a reaction chamber, the semiconductor device having a residue formed thereon,
(b) creating and maintaining a substantially oxygen free environment within the reaction chamber
(c) introducing etchant gasses into the reaction chamber, the etchant gasses including a hydrogen containing gas selected from the group consisting of ammonia and methane,
(d) applying energy to the etchant gasses to generate a plasma,
(d) exposing the semiconductor device to the plasma for a selected period of time.

13. The method of claim 12, wherein the etchant gasses include a hydrogen containing forming gas.

14. The method of claim 13, wherein the hydrogen containing forming gas includes a dilutant selected from the group consisting of, helium, argon, or nitrogen.

15. The method of claim 12, wherein water vapor is introduced to the reaction chamber.

16. The method of claim 15, wherein water vapor is generated using a catalytic moisture generator.
